(19) United States
(12) Patent Application Publication
(10) Pub. No.: US 2021/0149004 A1
(43) Pub. Date: May 20, 2021

(54) Estimation of dynamical properties of fluids using optical defects in solids

(71) Applicants: Maxim KHODAS, Ramat Gan (IL); Javier PRIOR, Ribera de Molina, Murcia (ES); Alex RETZKER, Jerusalem (IL); Daniel COHEN, Jerusalem (IL); Fedor JELEZKO, Ulm (DE)

(72) Inventors: Alex RETZKER, Jerusalem (IL); Daniel COHEN, Jerusalem (IL); Fedor JELEZKO, Cartagena (ES)

(21) Appl. No.: 17/052,185

(22) PCT Filed: May 30, 2019
(86) PCT No.: PCT/IL2019/050623

§ 371 Date: Nov. 9, 2020

Related U.S. Application Data
(60) Provisional application No. 62/677,970, filed on May 30, 2018.

(51) Int. Cl. G01R 33/46; G01R 33/32; G01R 33/30

(52) U.S. Cl. CPC G01R 33/46; G01R 33/30; G01R 33/32

(57) ABSTRACT

A novel method for measurement of velocity and diffusion constant in microfluidic channels is presented using nano-NMR techniques. The fluid molecules of interest interact with color centers implanted in a suitable substrate such as diamond. A magnetic dipolar interaction between the fluid molecule spins influences the state of the NV, which can be probed using known NMR techniques. The color center response is read out optically and the NMR spectrum can be reconstructed from this optical information.

The noise in the NMR spectra can be analyzed (e.g. in terms of its correlation function) to directly yield measurements of velocity and diffusion constant in the fluid, at orders of magnitude greater accuracy than otherwise possible.

### FIELD OF THE INVENTION

The present invention relates generally to the field of physical measurements, in particular estimation of velocity and diffusion coefficient.

### BACKGROUND OF THE INVENTION

Microfluidic channels have found increasing use and applications since their introduction in in the 1950's for inkjet printing. Nowadays, this technology is being used for biological, medical and chemical research, and finds commercial use in blood testing, printing, fuel cells, and more. Often processes which are normally carried out in a lab are miniaturised on a single chip in order to enhance efficiency and mobility as well as reducing sample and reagent volumes.

Despite their many applications, fundamental aspects regarding the physics of microfluidic channels remain a mystery. Specifically, the nature of flow near surfaces is still unknown both in the micro and macroscale. As technology advances, there will be a need to further narrow the cross-section of the microfluidic channels, and these ‘near surface’ effects will become dominant. The first step in understanding these phenomena is to be able to accurately measure their effects on physical properties such as velocity and diffusion coefficient.

Estimation of dynamical properties of the fluid flowing within the microfluidic channel, e.g. diffusion coefficient, temperature, and velocity, is still very challenging using current technology.

Typically, fluorescent molecules are injected into the channel and their propagation is tracked using a confocal microscope. Alternatively, the velocity can be determined by light scattering from a periodic array. Using fluorescent molecules can also be used to measure the diffusion coefficient of these molecules within a liquid. These methods lack in performance and only achieve an accuracy of about 5% for the mean channel velocity due to technical issues which include laser beam focusing and the temporal resolution of the camera.

Furthermore these techniques have fundamental disadvantages: 1. They allow only measurement of parameters (eg diffusion coefficient) related to the bead/dye within the fluid, and not those of the fluid itself; 2. When using a narrow enough channel, the dimensions of the bead/dye molecule will no longer be much less than those of the channel width, and will therefore affect the flow (the fluorescent molecules are often large, and in a small channel they can affect the flow profile). 3. The flow trajectories of these molecules generally pass through the middle of the tube (in a Poiseuille setting) because of the velocity gradient, which supplies little information about the flow profile near the surface.

It would thus answer a long-felt need to introduce a method for measurement of physical parameters of a fluid flow not requiring die, beads, or any other materials foreign to the fluid under measurement.

### SUMMARY OF THE INVENTION

Current advancements in nano-scale NMR provide a method of overcoming the aformentioned difficulties. Experimental groups at various universities have been able to use nitrogren vacancy (NV) centers in diamond to measure NMR signals and spectra of molecules that were on top of the diamond surface.

These NMR signals are greatly affected by physical parameters of the molecules on the diamond surface, including those mentioned above (temperature, velocity, diffusion coefficient).

For example in the paper “Microwave-assisted cross-polarization of nuclear spin ensembles from optically-pumped nitrogen-vacancy centers in diamond” a method is described using variable-magnetic-field, microwave-enabled cross-polarization to couple the NV electronic spin to protons in a model viscous fluid in contact with the diamond surface.

In this paper the authors measure the diffusion coefficient using polarization transfer. In contrast, we have, through systematic experimentation, discovered a nonintrusive technology with superior sensitivity.

In the method of our invention, fluid molecules interact with the NV centers in the diamond via a magnetic dipolar interaction (as opposed to cross-polarization of the prior art), which influences the state of the NV. This state is read out optically and the NMR spectrum can be reconstructed from this optical information.

The foregoing embodiments of the invention have been described and illustrated in conjunction with systems and methods thereof, which are meant to be merely illustrative, and not limiting. Furthermore just as every particular reference may embody particular methods/systems, yet not require such, ultimately such teaching is meant for all expressions notwithstanding the use of particular embodiments.

### BRIEF DESCRIPTION OF THE DRAWINGS

Embodiments and features of the present invention are described herein in conjunction with the following drawings:

FIG. 1A shows a cross section of one embodiment of the invention.

FIG. 1B is an SEM micrograph of one realization of the sample substrate of the invention.

FIG. 2 is a schematic depiction of the invention.

FIG. 3 shows a schematic depiction of another embodiment of the invention.

FIG. 4 shows a classic NMR setup.

FIG. 5 shows a setup for NMR on the nano scale

FIG. 6 shows the effects of polarization on an NV center

FIG. 7 shows the time dependence of the measured noise correlation function, with three characteristic time constants.

FIG. 8 shows two methods for calculation of the time constant t

### DETAILED DESCRIPTION OF PREFERRED EMBODIMENTS

The present invention will be understood from the following detailed description of preferred embodiments, which are meant to be descriptive and not limiting. For the sake of brevity, some well-known features, methods, systems, procedures, components, circuits, and so on, are not described in detail.

Molecules above a surface having NV or other color centers will interact with these centers via a magnetic dipolar interaction, which has a marked influence upon the state of the NV. This state can be read optically, and when interpreted correctly it can reconstruct the NMR spectra.

The NMR spectra of fluids is greatly affected by the aforementioned parameters of interest (velocity, diffusion coefficient, mixing ratio, etc). Thus, an accurate measurement of the NMR spectra can serve to estimate these parameters.

This method is based on the fact that the NV center is an excellent magnetometer at the nano scale that can read the magnetic field created by the nuclear spins effectively and thus replace the role of the coils in the regular NMR setting.

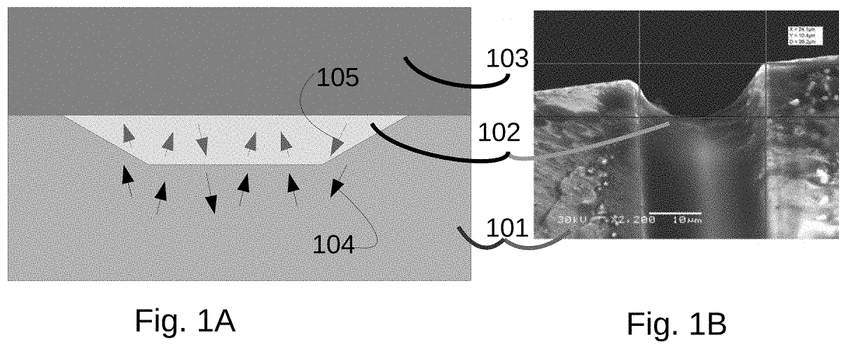

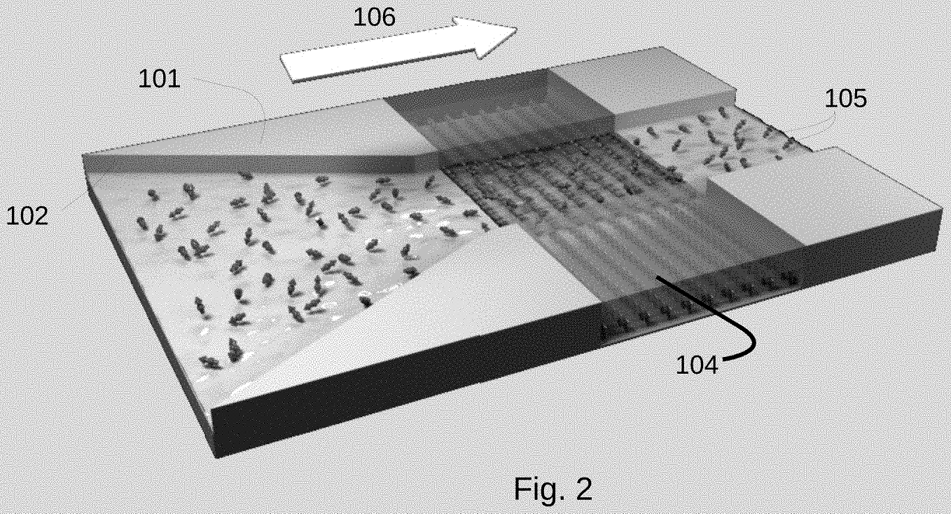

One implementation of a setup for the method is shown in the cross-sectional sketch of FIG. 1A, the micrograph of FIG. 1B, and the sketch of FIG. 2. Diamond 101 is provided having color centers 104 (such as NV centers for example) next to the surface of the diamond at a distance of e.g. 3 nanometers to a few micrometers. The NV centers 104 are produced within a few nanometers form the surface using ion implantation techniques growth of nitrogen doped layers on the ultrapure diamond substrate, or other means as will be clear to one skilled in the art

The diamond substrate 101 is provided with a microfluidic channel 102 suitable for conducting a fluid flow, the channel being produced by laser cutting, ion milling, chemical etch or plasma etch with masking, masked growth, or other means as again will be obvious to one skilled in the art.

Alternatively, flat diamond (without a channel) can be used and the channel can be integrated into the cover layer 103, which may be composed of PDMS for example. Other configurations can be used, as will be clear to one skilled in the art. For example, the diamond may be produced in the form of a sharp tip in which NV centers have been implanted, and this tip may used to probe existing channels, allowing measurements to be made of existing microfluidic systems by an external device consisting of the diamond tip, microscope objective (which may be used to support the diamond tip) and associated NMR equipment.

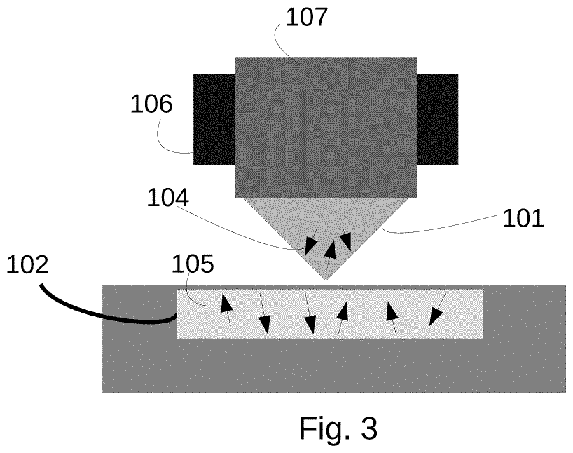

Such a setup is shown in FIG. 3, where the color centers 104 are embedded in a diamond tip 101 which is brought into close proximity to the channel 102 being investigated. This channel, carrying atoms or molecules having spins 105, may be investigated in a non-contact manner by the tip 101 which need only brought close enough that a signal is readable. The tip may for instance be deployed directly upon a microscope objective 107, which itself may be surrounded by RF/dc coils 106 adapted to produce an external magnetic field and/or RF pulse for carrying out the NMR measurement.

As mentioned the channel may in some embodiments covered by PDMS 103 (FIG. 1A) or other suitable material. Once the channel is produced (be it produced entirely in a single substrate, or formed by coupling three sides of one material to a cover of another material as in FIG. 1A, or otherwise), it can now usefully conduct a flow of fluid (the term incorporating liquids, gases, suspensions, superfluids, plasma, and the like). The channel is connected to capillaries and to a syringe or other source of pressure, such that fluids can be forced through the channel. The flow is perpendicular to the page in FIG. 1A, and in the direction of the arrow 106 in FIG. 2.

The random spins 105 in the flow are sensed by the NV centers 104, which respond optically (by emitting photons); this optical response is measured e.g. by a microscope or confocal microscope objective underneath the (optically transparent) diamond 101 or above the PDMS cover layer 103. The color centers are generally illuminated from the side opposite the objective although in principle the illumination may come from any direction.

The platform can be easily integrated with confocal microscope and microwave excitation means, and means for external magnetic field production (none of which are shown) necessary for the NMR measurements. The optical set-up needs to be equipped with high detection efficiency (high NA objective, highly sensitive detectors). Detection from the side of the channel or through a window from the side of PDMS can be used.

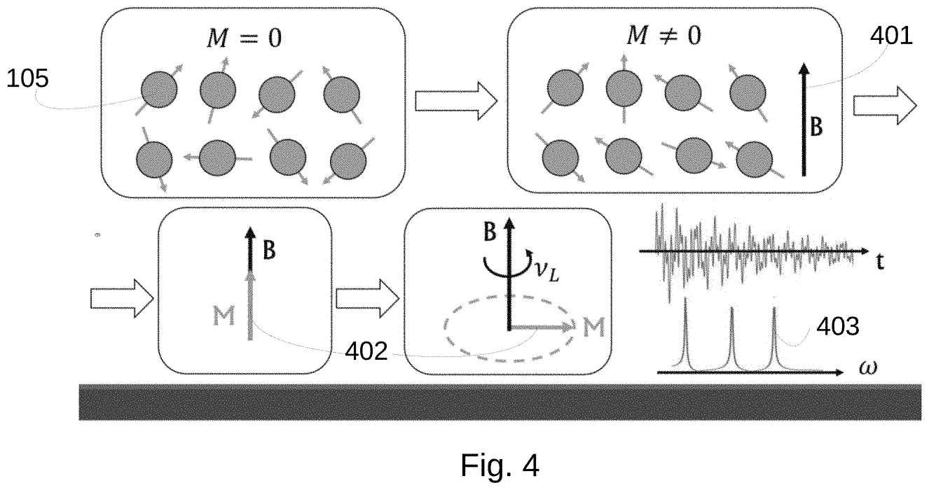

NMR We now briefly review the principles of NMR as relevant to the invention. In the classical NMR setup shown in FIG. 4, the spins under study 105 will generally have no net intrinsic magnetization, M=0. Upon application of an external field B (401), a net magnetization M≠0 (402) will be induced. If a brief additional external field is applied in a direction perpendicular to the original field B, the spins 105 will gain a component in this direction and will tend to precess around the original field 401 direction, at a set of frequencies 403 depending on the external field and moment of the spin 105. The field induced by this precession is read out by suitable coils and the spin of the sample 105 (amongst other characteristics) may now be determined.

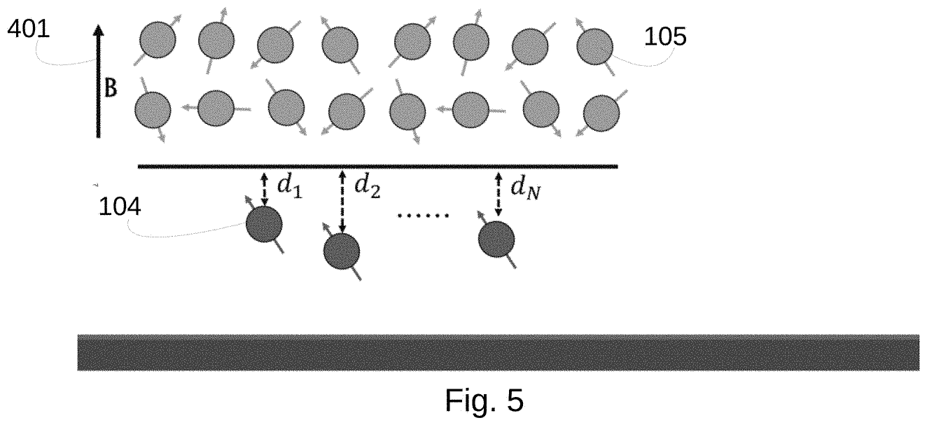

A nanoscale implementation of this setup is shown in FIG. 5, where NV centers 104 are used as probes of the NMR precession signal of the sample spins 105, instead of RF coils or other sense equipment; the NV centers respond optically to the field induced by the precession of the spins 105, and this optical response is used to measure the NMR spectrum.

In the nano-NMR setup, the external field 401 plays two roles;
1) To control the energy gap of the NV.
2) To control and increase the energy gap of the nuclei in the fluid; this is important as in high magnetic field the coherence time of the nuclei is longer.

The RF/microwave field is applied in order to probe a desired frequency in the power spectrum and to increase the coherence time of the NV.

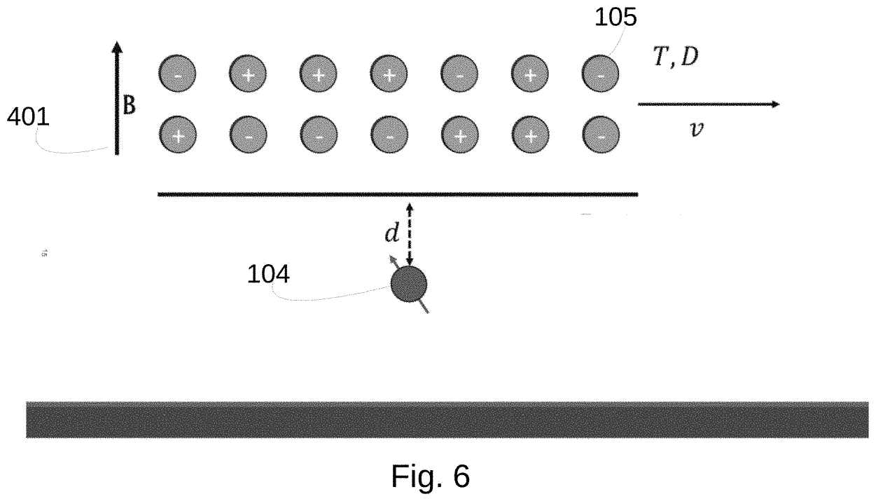

In FIG. 6 the spins 105 are shown in motion with a velocity v past the stationary NV centers 104. The spins 105 as they pass the NV centers 104 will elicit optical signal in the NV centers as described above, with time correlations between the signal produced being indicative of the velocity v of the fluid, as well as other parameters such as diffusion coefficient D, mixing ratio, and other physical parameters as will be clear to one skilled in the art.

As mentioned, the flow of spins 105 induces random magnetic fields at the locations of the NV centers. The power spectrum of the magnetic field noise can be estimated by optically probing the NV center. By analyzing the noise characteristics the flow properties can be deduced.

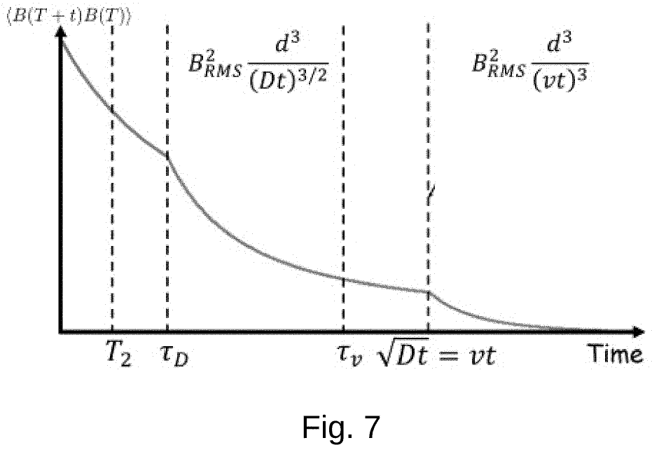

Specifically, the time dependence of the noise correlation function of the optical signal measured by the NV centers as shown in FIG. 7 has three characteristic time constants, the first of which τᵥ is related to the velocity,

v=d/τᵥ

where d is the distance from NV center to the diamond surface, while the second τ_{D} is related to the diffusion constant D

D=d²/τ_{D}

It should be noted that velocimetry methods using classic NMR techniques exist. These, however, usually relay on magnetic field gradient spin-echo experiments and therefore will not work in the micro- and nano-fluidic regimes due to the very low signal-to-noise of classic NMR devices.

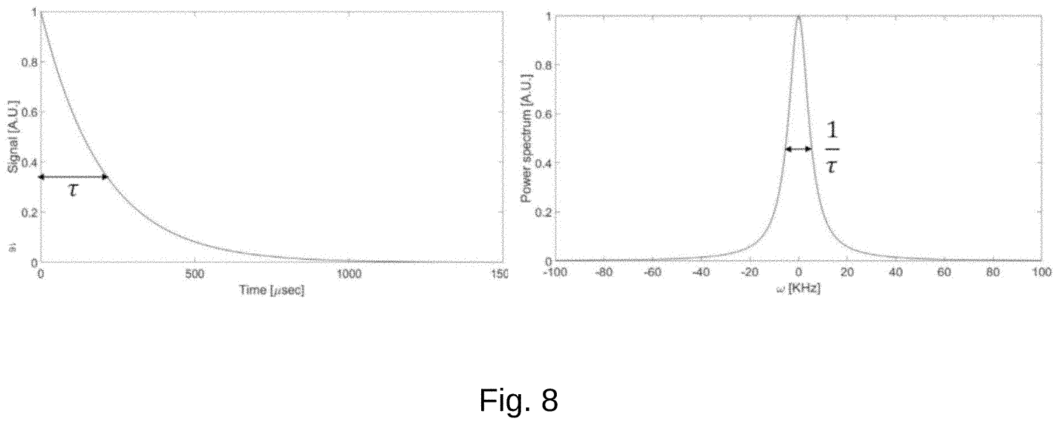

Using this non-intrusive technique we are able to measure velocity and diffusion coefficient with great accuracy as shown in FIG. 8, the sensitivity being given by

$$\frac{Δ v}{v} ∼ \frac{1}{\sqrt{T}}$$

where Δv is the error in velocity measurement and T the total measurement time.

Further aspects of the fluid being investigated may be derived from various parameters of measured signals including peak widths, peak positions, time constants, cross-correlations, and autocorrelations.

A further application of the device and method outlined above is estimating the mixing rate of two fluids in the reaction region, and to evaluate the flow properties next to the surface of the channel.

Other substrates may be used, for instance silicon carbide, metals oxides, and the like, the only requirement being that the substrate may be implanted with color centers. The substrate may itself be a thin layer applied upon another base, for instance CVD-deposited diamond upon a metal probe. The vacancies or dopants used for the color centers may also be of any type, the only requirement being that they produce photons that may travel through the rest of the substrate in sufficient intensity that they can be detected. Thus the main requirement is of compatibility between substrate and color centers—the substrate should be sufficiently transparent to the photons produced by the color centers that photons can travel through the substrate to eventually be detected externally.

The foregoing description and illustrations of the embodiments of the invention has been presented for the purposes of illustration. It is not intended to be exhaustive or to limit the invention to the above description in any form.

Any term that has been defined above and used in the claims, should be interpreted according to this definition.

The reference numbers in the claims are not a part of the claims, but rather used for facilitating the reading thereof. These reference numbers should not be interpreted as limiting the claims in any form.

1. A system for measurement of physical parameters of a fluid flow in a microfluidic channel consisting of:
a. a substrate implanted with color centers;
b. a microfluidic channel disposed at a distance of between 0 to 50 microns from said color centers; said channel being suitable for conducting a microfluidic flow;
d. dc and RF or microwave field production means adapted for production of NMR signals;
e. optical sensing means adapted to measure the optical activity of said color centers,
wherein said optical activity is affected by the physical parameters of said fluid flow.

2 .The system of claim 1 wherein said substrate fcrms one or more sides of said microfluidic channel.

3. The system of claim 1 wherein said color centers are implanted within a movable tip adapted to be brought into proximity of said microfluidic channel.

4. The system of claim 1 wherein said optical sensing means are disposed on a side of said substrate opposite said microfluidic channel, said substrate being largely transparent at the frequencies of interest and said optical signals from said channel passing through said substrate to said optical sensing means.

5. The system of claim 1, wherein said physical parameters are chosen from the group consisting of: velocity, diffusion constant, temperature, mixing rate, and fluid composition.

6. The system of claim 2, wherein said physical parameters are measured by means of the noise correlation function of said optical activity, wherein said velocity is given by the formula
v=d/τᵥ
where d is the distance from NV center to the diamond surface and τᵥ a first relaxation time of said correlation function, and wherein said diffusion constant D is given by the formula
D=d²/τ_{D}
where τ_{d} is a second relaxation time of said correlation function.

7. The system of claim 1 wherein said substrate is is selected from the group consisting of diamond, carbides, silicon carbide,metals, and metal oxides.

8. The system of claim 1 wherein said color centers are selected from the group consisting of: vacancies, substitutions, nitrogen vacancies, silicon vacancies; Di vacancies; and oxygen vacancies.

9. A method for measurement of physical parameters of a fluid flow in a microfluidic channel consisting of:
a. implanting color centers in a substrate;
b. providing a microfluidic channel disposed at a distance of between 0 to 50 microns from said color centers, said channel being suitable for conducting a microfluidic flow;
d. providing dc and RF or microwave fielc production means adapted for production of NMR signals;
e. forcing a fluid flow through said microfluid.c channel by suitable pumping means;
f. sensing the optical activity of said color centers by suitable optical sensing means;
wherein said parameters of said fluid flow are measured by means of the optical activity of said color centers.

10. The method of claim 9 wherein said substrate forms one or more sides of said microfluidic channel.

11. The method of claim 9 wherein said color centers are implanted within a movable tip adapted to be brought into proximity of said microfluidic channel.

12. The method of claim 9 wherein said optical sensing means are disposed on a side of said substrate opposite said microfluidic channel, said substrate being largely transparent at the frequencies of interest and said optical signals from said channel passing through said substrate to said optical sensing means.

13. The method of claim 9, wherein said physical parameters are chosen from the group consisting of: velocity, diffusion constant, temperature, mixing rale, and fluid composition.

14. The method of claim 9, wherein said physical parameters are measured by means of the noise correlation function of said optical activity, where.n said velocity is given by the formula
v=d/τᵥ
where d is the distance from NV center to the dianond surface and τᵥ a first relaxation time of said correlation function, and wherein said diffusion constant D is given by the formula
D=d²/τ_{D}
where τ_{d} is a second relaxation time of said correlation function.

15. The method of claim 9 wherein said substrate is diamond , carbides, silicon carbide, metals, and metal oxides.

16. The method of claim 9 wherein said color centers are selected from the group consisting of: vacancies, substitutions, nitrogen vacancies silicon vacancies; Di vacancies; and oxygen vacancies.

17. A system for measurement of physical parameters of a fluid flow in a microfluidic channel consisting of:
a. a substrate implanted with color centers;
b. a microfluidic channel disposed at a distance of between 0 to 50 microns from said color centers;
said channel being suitable for conducting a microfluidic flow;
d. dc and RF or microwave field production means adapted for production of NMR signals;
e. optical sensing means adapted to measure the optical activity of said color centers;
f. measuring the noise correlation of said optical activity, which is affected by the physical parameters of said fluid flow;
wherein the velocity of said fluid flow is given by the formula
v=d/τᵥ
where d is the distance from said color centers to said substrate surface and τᵥ a first relaxation time of said correlation function, and wherein the diffusion constant D of said fluid flow is given by the formula
D=d²/τ_{D}
where τ_{D} is a second relaxation time of said correlation function.

18. The system of claim 17 wherein said substrate forms one or more sides of said microfluidic channel.

19. The system of claim 17 wherein said color centers are implanted within a movable tip adapted to be brought into proximity of said microfluidic channel.

20. The system of claim 17 wherein said optical sensing means are disposed on a side of said substrate opposite said microfluidic channel, said substrate being largely transparent at the frequencies of interest and said optical signals from said channel passing through said substrate to said optical sensing means.

21. The system of claim 17, wherein said physical parameters are chosen from the group consisting of: velocity, diffusion constant, temperature, mixing rate, and fluid composition.

22. The system of claim 1 wherein said substrate is is selected from the group consisting of: diamond, carbides, silicon carbide, metals, and metal oxides.

23. The system of claim 17 wherein said color centers are selected from the group consisting of: vacancies, substitutions, nitrogen vacancies, silicon vacancies; Di vacancies; and oxygen vacancies.

24. A method for measurement of physical parameters of a fluid flow in a microfluidic channel consisting of:
a. implanting color centers in a substrate;
b. providing a microfluidic channel disposed at a distance of between 0 to 50 microns from said color centers, said channel being suitable for conducting a microfluidic flow;
d. providing dc and RF or microwave field production means adapted for production of NMR signals;
e. forcing a fluid flow through said microfluidic channel by suitable pumping means;
f. sensing the optical activity of said color centers by suitable optical sensing means;
g. measuring the noise correlation function of said optical activity
wherein the velocity v of said fluid flow is given by the formula
v=d/τᵥ
where d is the distance from said color centers to said substrate surface, and τᵥ a first relaxation time of said correlation function, and wherein the diffusion constant D of said fluid flow is given by the formula
D=d²/τ_{D}
where τ_{D} is a second relaxation time of said correlation function.

25. The method of claim 24 wherein said substrate forms one or more sides of said microfluidic channel.

26. The method of claim 24 wherein said color centers are implanted within a movable tip adapted to be brought into proximity of said microfluidic channel.

27. The method of claim 24 wherein said optical sensing means are disposed on a side of said substrate opposite said microfluidic channel, said substrate being largely transparent at the frequencies of interest and said optical signals from said channel passing through said substrate to said optical sensing means.

28. The method of claim 24, wherein said physical parameters are chosen from the group consisting of: velocity, diffusion constant, temperature, mixing rate, and fluid composition.

29. The method of claim 24 wherein said substrate is selected from the group consisting of: diamond, carbides, silicon carbide, metals, and metal oxides.

30. The method of claim 24 wherein said color centers are selected from the group consisting of: vacancies, substitutions, nitrogen vacancies, silicon vacancies, Di vacancies, and oxygen vacancies.
